(19) United States
(12) Patent Application Publication
(10) Pub. No.: US 2003/0140958 A1
(43) Pub. Date: Jul. 31, 2003

(54) Solar photoelectric module

(76) Inventors: Cheng-Chieh Yang, Taipei (TW); Hsin Chung Chao, Taipei (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/056,041

(22) Filed: Jan. 28, 2002

(51) Int. Cl. H01L 25/00

(52) U.S. Cl. 136/244; 136/246

(57) ABSTRACT

The present invention provides a solar photoelectric module having the two-sided light-absorbing characteristic to converse light energy source into electric energy source. The present solar photoelectric module comprises a solar cell module and a backlight module which is arranged at a backlight position of the photoelectric module so as to the present solar photoelectric module can directly absorb the solar light by the solar plate and utilizes the light-condensing effect of a backlight module and the two-sided light-absorbing effect to improve the output efficiency of the light source. The present invention further provides with advantages of high absorbing efficiency, small volume, and saving more space and it can apply to many related solar products.

### BACKGROUND OF THE INVENTION

1. Field of the Invention

The present invention generally relates to a solar photoelectric module, and more particularly relates to a solar photoelectric module combining a solar cell module and a backlight module, wherein the solar photoelectric module utilizes the characteristic of two-sided light-absorbing to improve the output efficiency of the light source.

2. Description of the Prior Art

As well known, the science and the technology are fast changed with each passing day and the energy source is progressively depleted due to the requirement from the science and the technology. Hence, the limited natural resources should be effectively utilized. Currently, electric equipments used in the routine life are all depending on the electric power conversed from the natural resources. However, the overuse of the energy source causes the ruining of environment and it do not allow to ignore this situation. For this purpose, a pollution-free solar generating electric power system generally be paid much attention by the public.

Accordingly, with the improvement and the universal of the science and the technology, the solar power system is commonly used in various kinds of our routine living, such as the street light system, the illumination of the advertisement billboard, and the auxiliary electric power. Prior solar cell module usually utilizes the single side of the solar plate to illuminate light so as to absorb the solar energy to converse into the electric energy for common use. Even if this module design of the single side light-illumination provides with the advantage of small size, but this design relatively provide with the disadvantage of low light-absorbing efficiency and it do not fill the current trend of the high efficiency.

In order to improve the output efficiency of the light source, Japan Sanyo develops another two-sided light-illuminating solar cell module, such as shown in the FIG. 1. The solar cell module 10 provides with two-sided a solar plate 12 and a solar plate 14. The two-sided light-illuminating solar cell module 10 is capable to incline arrange to make the top solar plate 12 face up to directly absorb the illuminating solar light. Besides, a reflecting plate 16 is arranged at a backlight horizontal position of the solar cell module 10 to reflect the solar light to the solar plate 14 to achieve the purpose for two-sided light-absorbing.

Obviously, the main spirit of the present invention is to provide a solar photoelectric module which simultaneously combines the advantages of small size, high light-absorbing efficiency, and time limitation free and then some disadvantages of well-known technology are overcome.

### SUMMARY OF THE INVENTION

The primary object of the present invention is to provide a solar photoelectric module, wherein the module utilizes the light-condensing effect of a backlight module and the two-sided light-absorbing effect of a solar cell module to improve the output efficiency of the light source.

Another object of the present invention is to provide a solar photoelectric module to simultaneously combine advantages of high absorbing efficiency, small volume, and saving more space and it can apply to many related solar products.

A further object of the present invention is to utilize the design of the present solar photoelectric module, wherein no matter what the illuminating angle of the solar light is, the present design still can achieve the two-sided light-absorbing characteristics.

In order to achieve previous objects, the present invention comprises following elements. First, a solar cell module is provided with a two-sided solar plate. Then, a backlight module is arranged at a backlight position of the solar cell module. Wherein the backlight module further comprises a light-condensing convex portion, which is looped-arranged around the solar cell module, and a light-transmitting plate, which is arranged at the backlight position of the solar cell module.

Another embodiment of the solar photoelectric module of the present invention comprises following elements. First, a plurality of solar cell modules are provided and each of them is respectively provided with a two-sided solar plate. Then, a plurality of backlight modules are arranged at interval with those solar cell modules. Wherein at least one lateral side of those backlight modules is convex to form a light-condensing convex portion and each of those backlight modules comprises a light-transmitting plate having relative two lateral-sides to make each light-transmitting plate corresponding to each solar plate.

### BRIEF DESCRIPTION OF THE DRAWINGS

The foregoing aspects and many of the accompanying advantages of this invention will become more readily appreciated as the same becomes better understood by reference to the following detailed description, when taken in conjunction with the accompanying drawings, wherein:

FIG. 1 is a schematic representation of a solar cell module, in accordance with prior techniques;

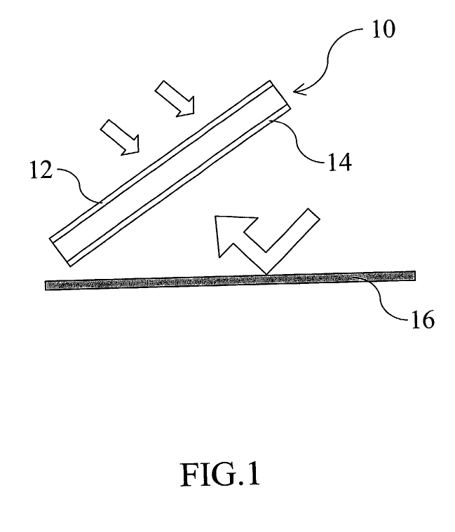

FIG. 2 is a vertical-view schematic representation of a solar photoelectric module, in accordance with the present invention;

FIG. 3 is a cutaway-view schematic representation of a solar photoelectric module, in accordance with the present invention;

FIG. 4 is a schematic representation of a solar photoelectric module, in accordance with another preferred embodiment of the present invention; and

FIG. 5 is an assembly schematic representation in accordance with the FIG. 4.

### DESCRIPTION OF THE PREFERRED EMBODIMENT

The present invention provides a solar photoelectric module utilizes a solar cell module and a backlight module which is arranged at a backlight position of the photoelectric module so as to the present solar photoelectric module can directly absorb the solar light by the solar plate and utilizes the light-condensing effect of a backlight module and the two-sided light-absorbing effect to improve the output efficiency of the light source.

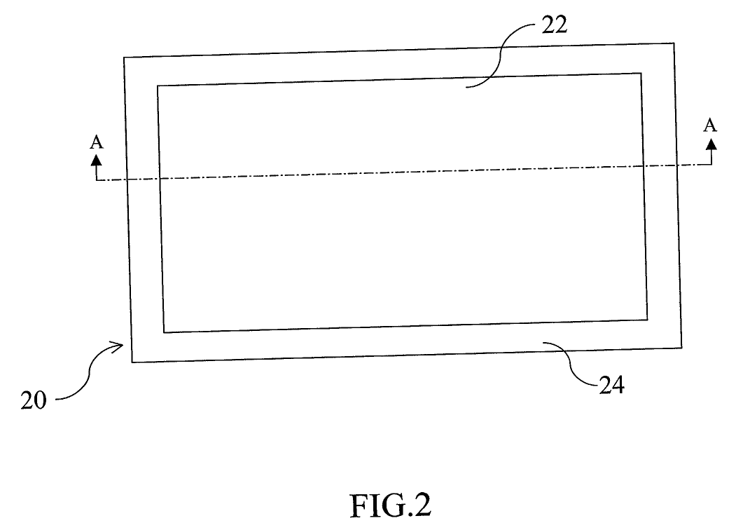

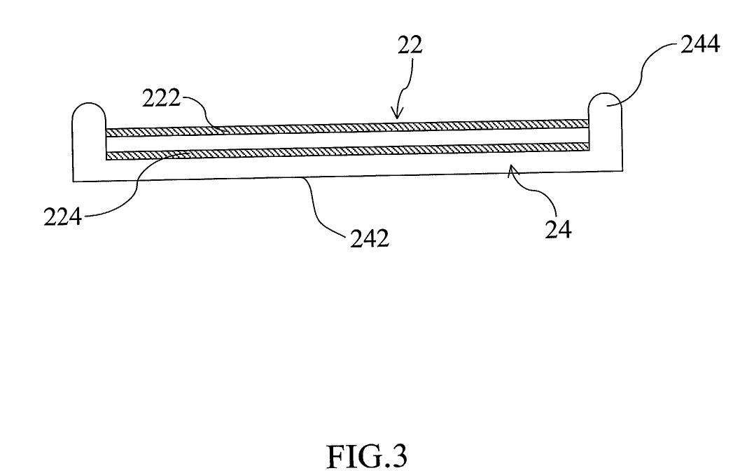

FIG. 2 and FIG. 3 are a vertical-view schematic representation and a cutaway-view schematic representation of an A-A line segment of the present invention. A solar photoelectric module converses light energy source into electric energy source. The present solar photoelectric module comprises a solar cell module and a backlight module. As shown in figures, the solar photoelectric module 20 comprises a solar cell module 22, wherein a top outside surface and a under outside surface of the solar cell module 22 respectively provide with a light-absorbing solar plate 222 and a light-absorbing solar plate 224. Between the light-absorbing solar plate 222 and the light-absorbing solar plate 224 are arranged with cell, recharge/discharge controller and DC/AC switcher, which are not shown in figures, to converse light energy source absorbing from the solar plate into electric energy source for common electric equipments use. A backlight module 24 is arranged at a backlight position of the solar cell module 22, wherein the backlight module 24 comprises a light-transmitting plate 242 arranged at the backlight position of the solar cell module 22 and a light-condensing convex portion 244 looped-arranged around the solar cell module 22.

Generally, the mentioned light-transmitting plate 242 is provide with an light-obstructing pattern to utilize the light-transmitting plate 242 to uniformly reflect the collecting light source from the light-condensing convex portion 244 to the backside solar plate 224 of the solar cell module 22, and the light-obstructing pattern of the light-transmitting plate 242 is formed closely or loosely in accordance with a distance from the light-condensing convex portion 244.

In operation, when the light source is illuminating on the solar photoelectric module 20, the solar cell module 22 utilizes the solar plate 222 on the top outside surface directly light-absorbing to converse light energy source into electric energy source. On the other hand, the solar plate 24 utilizes the light-condensing convex portion 244 to condensate the light source to the light-transmitting plate 242 and then the light-transmitting plate 242 uniformly reflect the collecting light source condensing from the light-condensing convex portion 244 to a backside solar plate 224 of the solar cell module 22. So as the solar plate 224 can still absorb the light source even in the situation that there is no directly illuminating light source on the solar plate 224 to achieve two-sided light-absorbing effect and to improve the output efficiency of the light source.

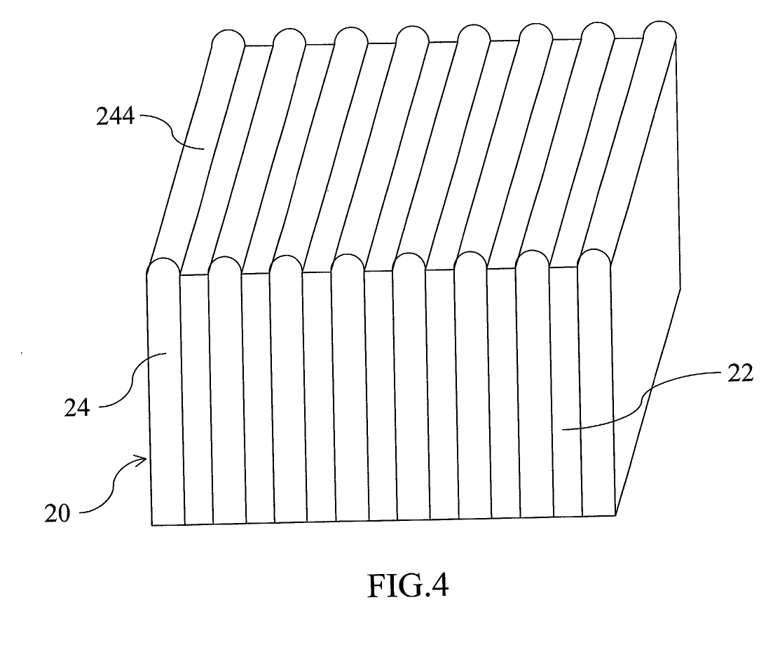

In an alternative embodiment of the present invention illustrated in the FIG. 4, a solar photoelectric module 20 comprises a plurality of solar cell modules 22, which are respectively provided with two-sided a light-absorbing solar plate thereon (not shown in the Figure); and a plurality of backlight modules 24, which are arranged at interval with those solar cell modules 22. Wherein, at the sun-facing side of those backlight modules 24 is convex and provided with the light-condensing convex portion 244 and two lateral-sides of each of those backlight modules 24 respectively comprise a light-transmitting plate (not shown in the Figure) to make each of those light-transmitting plates corresponding to each of those solar plates. Wherein, the light-transmitting plate is provide with an light-obstructing pattern to utilize the light-transmitting plate to uniformly reflect the collecting light source from the light-condensing convex portion to a backside solar plate of the solar cell module and the light-obstructing pattern of the light-transmitting plate is formed closely or loosely in accordance with a distance from the light-condensing convex portion.

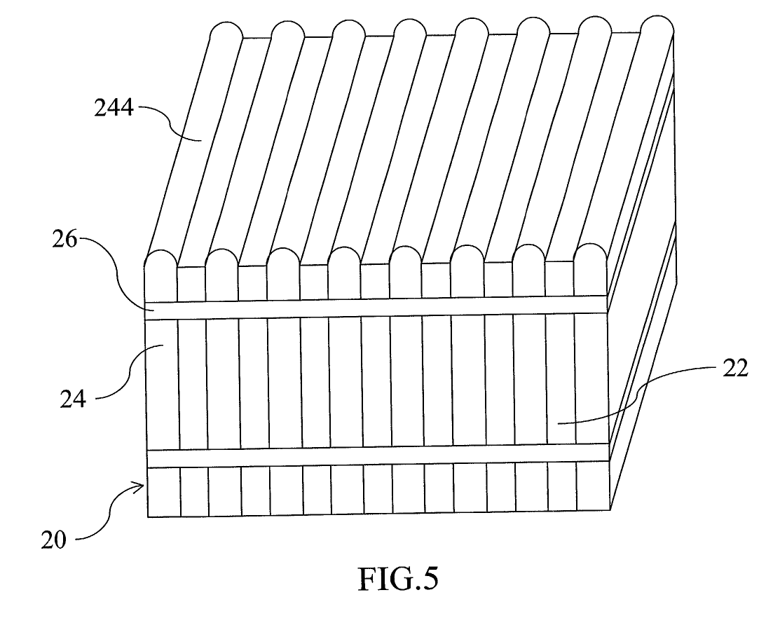

More specifically, a mode to assemble those solar cell modules 22 and those backlight modules 24, which are arranged at interval with each other is shown in the FIG. 5. A fixing strip 26 is arranged surrounding the solar photoelectric module 20 to connect those solar cell modules 24 and those backlight modules 24 for the purpose to fix four surfaces. Besides, the fixing strip can also be substitute for fastener connecting, adhering connecting, tenon connecting, and the like to assemble those solar cell modules 22 and those backlight modules 24.

In view of the forgoing, the present invention utilizes the light-condensing effect of a backlight module and the two-sided light-absorbing effect to improve the output efficiency of the light source. The present invention further provides with advantages of high absorbing efficiency, small volume, and saving more space and it can apply to many related solar products.

As the mention above, the description of the embodiments of the invention has been presented for purposes of illustration and description, and is not intended to be exhaustive or to limit the invention to be precise from disclosed. The description was selected to best explain the principles of the invention and practical application of these principles to enable others skilled in the art to best utilize the invention in various embodiments and modifications as are suited to the particular use contemplated. It is intended that the scope of the invention not to be limited by the specification, but be defined by the claim set forth below.

What is claimed is:

1. A solar photoelectric module which can absorb solar energy source to converse into electric energy source, said module comprising:
a solar cell module provided with a two-sided light-absorbing solar plate; and
a backlight module arranged at a backlight position of said solar photoelectric module, wherein a lateral side of said backlight module is convex and looped-arranged around said solar cell module.

2. The solar photoelectric module according to claim 1, wherein said backlight module comprises a light-condensing convex portion looped-arranged around said solar cell module and a light-transmitting plate arranged at said backlight position of said solar cell module.

3. The solar photoelectric module according to claim 2, wherein said light-transmitting plate is provide with an light-obstructing pattern to utilize said light-transmitting plate to uniformly reflect the collecting light source from said light-condensing convex portion to a backside solar plate of said solar cell module.

4. The solar photoelectric module according to claim 3, wherein said light-obstructing pattern of said light-transmitting plate is formed closely or loosely in accordance with a distance from said light-condensing convex portion.

5. A solar photoelectric module which can absorb solar energy source to converse into electric energy source, said module comprising:
a plurality of solar cell modules respectively provided with a two-sided light-absorbing solar plate; and
a plurality of backlight modules which are arranged at interval with said solar cell modules, wherein at least one lateral side of said backlight module is convex and looped-arranged around said solar photoelectric module.

6. The solar photoelectric module according to claim 5, wherein each of those said backlight modules further comprises a light-transmitting plate having relative two lateral-sides to make each of those said light-transmitting plates corresponding to each of those said solar plates.

7. The solar photoelectric module according to claim 6, wherein each of said light-transmitting plate is provide with an light-obstructing pattern to utilize said light-transmitting plate to uniformly reflect the collecting light source from said light-condensing convex portion to a backside solar plate of said solar cell module.

8. The solar photoelectric module according to claim 7, wherein said light-obstructing pattern of said light-transmitting plate is formed closely or loosely in accordance with a distance from said light-condensing convex portion.

9. The solar photoelectric module according to claim 5, wherein the way to connect those said solar cell modules and those said backlight modules at interval with each other can be selected by the group of fastener connecting, adhering connecting, and tenon connecting.
